(19) United States
(12) Patent Application Publication
(10) Pub. No.: US 2015/0188009 A1
(43) Pub. Date: Jul. 2, 2015

(54) METHOD OF MANUFACTURING SEMICONDUCTOR DEVICE

(71) Applicant: Lextar Electronics Corporation, Hsinchu (TW)

(72) Inventors: Wen-Ying CHIH, Taichung City (TW); Nai-Wei HSU, Tainan City (TW); Te-Chung WANG, Taichung City (TW)

(21) Appl. No.: 14/304,817

(22) Filed: Jun. 13, 2014

(30) Foreign Application Priority Data
Dec. 30, 2013 (TW) 102148949

(51) Int. Cl. H01L 33/58; H01L 33/00

(52) U.S. Cl. CPC H01L 33/58; H01L 33/0095

(57) ABSTRACT

The present disclosure provides a method of manufacturing a semiconductor device, including providing a semiconductor structure including a sequential stack of an n-type semiconductor layer, an active layer, and a p-type semiconductor layer. A first metal layer and a second metal layer on the first metal layer are formed on the semiconductor structure. A heat treatment process is performed, such that the first metal layer is oxidized to form a first metal oxide layer and the second metal layer is reversed to form a second metallic compound layer between the first metal oxide layer and the p-type semiconductor layer. The first metal oxide layer and the second metallic compound layer are removed. A mesa etching process is performed after performing the heat treatment process, to form a mesa region exposing a part of the n-type semiconductor layer.

### CROSS REFERENCE TO RELATED APPLICATIONS

This application claims priority of Taiwan Patent Application No. 102148949, filed on Dec. 30, 2013, the entirety of which is incorporated by reference herein.

### BACKGROUND OF THE INVENTION

1. Field of the Invention

The present disclosure relates to semiconductor technology, and in particular relates to a method of manufacturing a semiconductor device that can increase carrier concentration and improve brightness.

2. Description of the Related Art

Light-emitting diode (LED) is a semiconductor device that can convert electrical energy into light energy, which includes at least a p-n junction constituted of, for example, a p-type semiconductor layer and an n-type semiconductor layer. When an appropriate bias is applied to the p-n junction, the electrons combine with the holes at the p-n junction and release energy. If the energy is released as light, a luminescence phenomenon happens.

To reduce the driving voltage of the light-emitting diodes and to improve the luminous efficiency of light-emitting diodes, various manufacturing technologies for the light-emitting diodes have been developed in recent years. In conventional light-emitting diode manufacturing processes, it is difficult to form a good Ohmic contact by a current-spreading layer composed of pure metals with a p-type semiconductor layer since the p-type semiconductor layer has a high work function. In order to reduce the contact resistance between the current-spreading layer and the p-type semiconductor layer, more than one type of metal is used to form the current-spreading layer. However, the design of the light-emitting diodes would be limited in currently known light-emitting diode manufacturing processes. Moreover, the luminous efficiency obtained by such manufacturing processes needs to be improved.

Therefore, though the existing manufacturing technologies of the light-emitting diodes have been used in various applications, a manufacturing method that can further reduce the driving voltage of the light-emitting diodes and improve the luminous efficiency of the light-emitting diodes is still under requirement.

### BRIEF SUMMARY OF THE INVENTION

A detailed description is given in the following embodiments with reference to the accompanying drawings.

An embodiment of the present disclosure involves a method of manufacturing a semiconductor device. The method comprises providing a semiconductor structure, including a sequential stack of an n-type semiconductor layer, an active layer, and a p-type semiconductor layer. A first metal layer and a second metal layer are formed on the semiconductor structure, wherein the second metal layer is disposed on the first metal layer. A heat treatment process is performed such that the first metal layer is oxidized to form a first metal oxide layer and the second metal layer is reversed to form a second metallic compound layer between the first metal oxide layer and the p-type semiconductor layer. The first metal oxide layer and the second metallic compound layer are then removed, and a mesa etching process is performed after performing the heat treatment process to remove a part of the p-type semiconductor layer, a part of the active layer, and a part of the n-type semiconductor layer, to form a mesa region exposing another part of the n-type semiconductor layer.

### BRIEF DESCRIPTION OF THE DRAWINGS

The present disclosure can be more fully understood by reading the subsequent detailed description and examples with references made to the accompanying drawings, wherein:

FIGS. 1A-1E are cross-sectional views of the semiconductor device at various intermediate stages in the method of manufacturing a semiconductor device according to the embodiments of the present disclosure.

### DETAILED DESCRIPTION OF THE INVENTION

The following description is set forth in order to provide a thorough understanding of the disclosed embodiments. The following description and the drawings are made for the purpose of illustrating the general principles of the disclosure and should not be taken in a limiting sense. The present disclosure may repeat reference numerals and/or letters in the various examples. This repetition is for the purpose of simplicity and clarity and does not in itself dictate a relationship between the various embodiments and/or drawings discussed. The scope of the invention is best determined by reference to the appended claims.

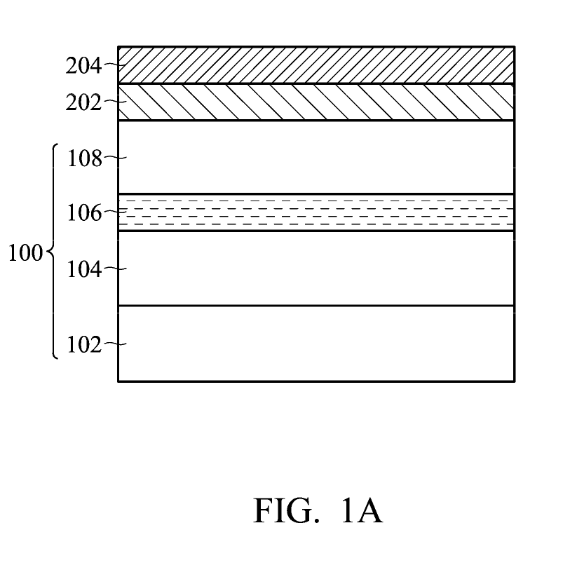

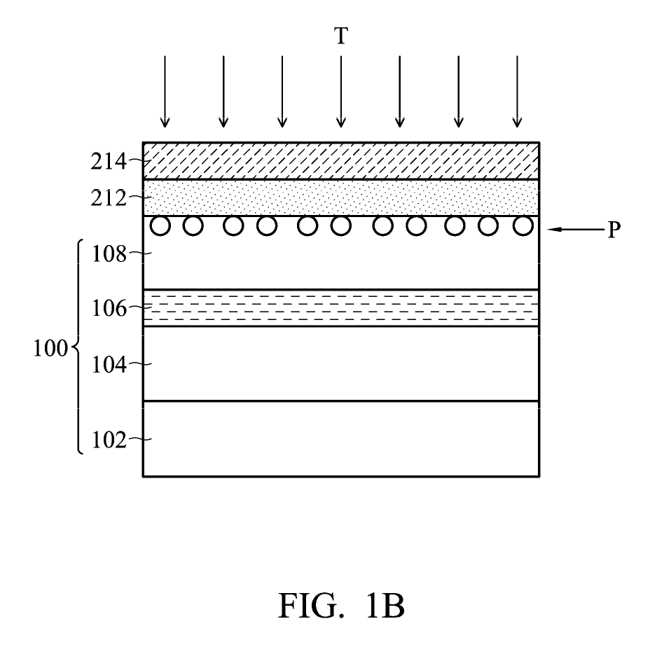

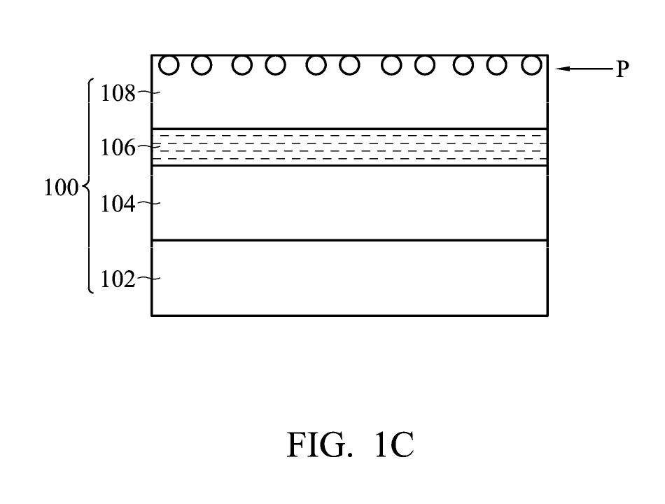

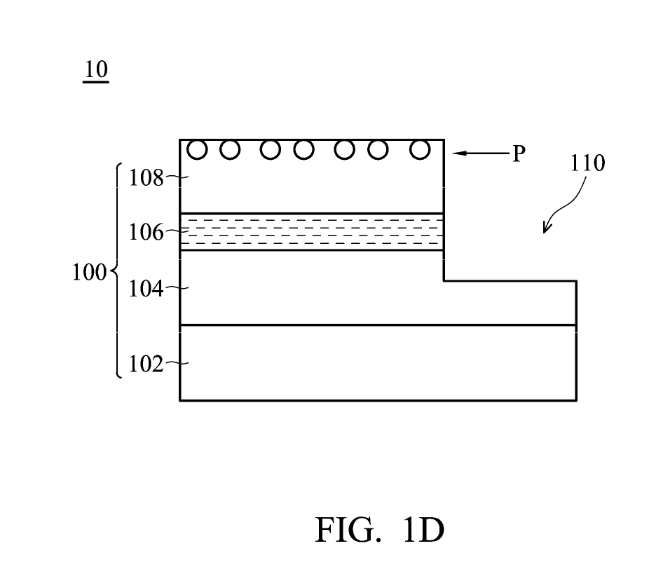

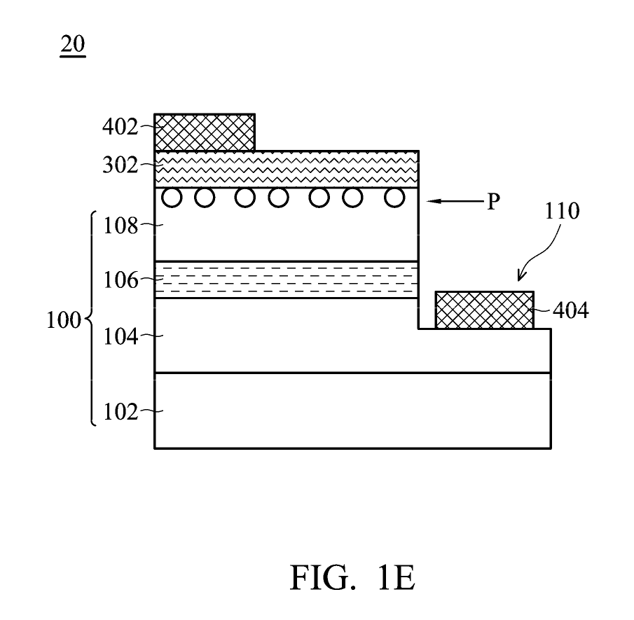

FIGS. 1A-1E are cross-sectional views of a semiconductor device at various intermediate stages in a method of manufacturing the semiconductor device according to an embodiment of the present disclosure.

Refer to FIG. 1A, first, a semiconductor structure 100, including a sequential stack of an n-type semiconductor layer 104, an active layer 106, and a p-type semiconductor layer 108 on a substrate 102 is provided. The substrate 102 may function as a carrier for epitaxy and/or support, and may be a conductive or non-conductive transparent material. In the present embodiment, a sapphire substrate is used as the substrate 102, but it is not limited thereto. For example, the substrate 102 may also include gallium arsenide (GaAs), gallium nitride (GaN), aluminum nitride (AlN), indium nitride (InN), indium phosphide (InP), aluminum gallium nitride (AlGaN), indium gallium nitride (InGaN), silicon carbide (SiC), zinc oxide (ZnO), aluminum-doped zinc oxide (AZO), or a combination thereof.

The n-type semiconductor layer 104, the active layer 106 and the p-type semiconductor layer 108 may each be a single-layer structure or a multilayer structure. In the present embodiment, the n-type semiconductor layer 104, the active layer 106 and the p-type semiconductor layer 108 constitute a light-emitting diode structure. The active layer 106 may have a single heterostructure (SH), a double heterostructure (DH) or a multi-quantum well (MQW) structure, and the emission wavelength of the light-emitting diode structure can be adjusted by modifying the composition of the material constituting the active layer 106. The n-type semiconductor layer 104, the active layer 106 and the p-type semiconductor layer 108 may include gallium (Ga), aluminum (Al), indium (In), nitrogen (N), arsenic (As), phosphorus (P), silicon (Si), a compound thereof, or a combination thereof. Moreover, the n-type semiconductor layer 104 may further include an n-type dopant (for example, silicon) and the p-type semiconductor layer 108 may further include a p-type dopant (for example, magnesium). In the present embodiment, the n-type semiconductor layer 104 is n-type doped gallium nitride (n-GaN), the active layer 106 has a multi-quantum well structure, and the p-type semiconductor layer 108 is p-type doped gallium nitride (p-GaN). The n-type semiconductor layer 104, the active layer 106 and the p-type semiconductor layer 108 may be formed using any suitable epitaxial growth process. In the present embodiment, the n-type semiconductor layer 104, the active layer 106 and the p-type semiconductor layer 108 are epitaxially grown on the substrate 102 in sequence by a metal-organic chemical vapor deposition (MOCVD) process.

Continue to refer to FIG. 1A. After providing the semiconductor structure 100, a first metal layer 202 and a second metal layer 204 are formed on the semiconductor structure 100, wherein the second metal layer 204 is disposed on the first metal layer 202. In the present embodiment, the work function of the first metal layer 202 and that of the second metal layer 204 are greater than that of the p-type semiconductor layer 108. The first metal layer 202 may include nickel (Ni), platinum (Pt), or rhodium (Rh). The second metal layer 204 may include gold (Au). The first metal layer 202 and the second metal layer 204 may be formed using any suitable method, such as physical or chemical vapor deposition, evaporation, sputtering, electroplating, or other suitable methods. In the present embodiment, a nickel layer is formed on the semiconductor structure 100 by evaporation to serve as the first metal layer 202 and a gold layer is formed on the first metal layer 202 by evaporation to serve as the second metal layer 204, thereby obtaining a nickel/gold stack constituted of the first metal layer 202 and the second metal layer 204.

Then, refer to FIGS. 1A-1B, a heat treatment process T is performed on the semiconductor structure 100, the first metal layer 202 and the second metal layer 204. The first metal layer 202 and the second metal layer 204 are “reversed” at this step, wherein the atoms of the first metal layer 202 are reversed to the top surface of the laminated structure and oxidized to form a first metal oxide layer 214, while the atoms of the second metal layer 204 are reversed to form a second metallic compound layer 212 between the first metal oxide layer 214 and the p-type semiconductor layer 108, as shown in FIG. 1B. The heat treatment process T may be performed at a temperature in a range of 100-800° C. In the present embodiment, the heat treatment process T is performed at a temperature in a range of 200-400° C. The heat treatment process T includes utilizing an atmosphere containing nitrogen and oxygen, wherein the ratio of nitrogen and oxygen (N₂:O₂) in the atmosphere is between 100:1-1:100.

In the present embodiment, a p-type doped GaN is used as the p-type semiconductor layer 108, and a nickel layer and a gold layer are used as the first metal layer 202 and the second metal layer 204, respectively. During performing the heat treatment process T, the gold atoms of the second metal layer 204 may pass through the first metal layer 202 and diffuse toward the p-type semiconductor layer 108, thereby forming a gold-rich second metallic compound layer 212 in the first metal layer 202. The gold atoms of the second metal layer 204 may also diffuse into the p-type semiconductor layer 108 and occupy the lattice sites of the gallium atoms that constitute the p-type semiconductor layer 108, such that a large number of vacancies are formed in the p-type semiconductor layer 108. As a result, a carrier concentrated region P is formed in the p-type semiconductor layer 108, as shown in FIG. 1B. The carrier concentrated region P increases the p-type carrier (i.e., holes) concentration in the p-type semiconductor layer 108. Therefore, the series resistance formed by the p-type semiconductor layer 108 and the subsequently formed current-spreading layer 302 or electrode layer 402 (described later with reference to FIG. 1E) is reduced, the electron-hole recombination probability is increased, and the brightness of the semiconductor device is improved. At the same time, the heating temperature of the heat treatment process T facilitates the breaking of the Mg—H bonds in the p-type semiconductor layer 108 and further increases the p-type carrier concentration in the p-type semiconductor layer 108. On the other hand, due to the heating temperature of the heat treatment process T, the nickel atoms of the first metal layer 202 diffuse toward the surface of the second metal layer 204 and react with the oxygen in the heat treatment atmosphere, such that the first metal oxide layer 214 is formed.

After the heat treatment process T is completed, an etching solution having a pH value less than 10 may be used to remove the first metal oxide layer 214 and the second metallic compound layer 212, thereby obtaining a semiconductor structure 100 with a carrier concentrated region P formed at the surface of the p-type semiconductor layer 108, as shown in FIG. 1C. In the present embodiment, a hydrochloric acid (HCl) is used as the etching solution. Thereafter, as shown in FIG. 1D, a mesa etching process is performed on the semiconductor structure 100 with the carrier concentrated region P to remove parts of the p-type semiconductor layer 108, the active layer 106, and the n-type semiconductor layer 104, to form a mesa region 110 exposing another part of the n-type semiconductor layer 104. As a result, a semiconductor device 10 is obtained.

It is noted that the heat treatment process T must be performed before the mesa etching process. If the heat treatment process T is performed after the mesa etching process, the atomic bonds in the part of the n-type semiconductor layer 104 that are exposed from the mesa region 110 may be broken due to the heating temperature of the heat treatment process T, therefore resulting in the formation of defects. In consequence, the electrons may be captured by the defects more easily in the semiconductor device, and the electrical properties of the semiconductor device may be deteriorated. Accordingly, it is not desired.

Thereafter, other desired features may be formed on the semiconductor device 10 using any suitable semiconductor manufacturing technology to obtain a complete electronic device structure. For example, a p-type electrode and an n-type electrode (not shown) may be formed on the p-type semiconductor layer 108 and on the mesa region 110 that exposes another part of the n-type semiconductor layer 104, respectively, to electrically connect the p-type semiconductor layer 108 and the n-type semiconductor layer 104 to an external circuit.

In another embodiment, after removing the first metal oxide layer 214 and the second metallic compound layer 212, as shown in FIG. 1C, a current-spreading layer (not shown) may be formed on the p-type semiconductor layer 108 with the carrier concentrated region P. Then, the mesa etching process shown in FIG. 1D may be performed, and a p-type electrode and a n-type electrode may be formed on the p-type semiconductor layer 108 and on the mesa region 110, respectively, such that a semiconductor device 20 shown in FIG. 1E is obtained. The semiconductor device 20 includes a current-spreading layer 302, a p-type electrode 402 and an n-type electrode 404, wherein the current-spreading layer 302 includes a transparent conductive layer. The transparent conductive layer may include a nickel/gold stack or an oxide layer (for example, Indium tin oxide).

Table 1 shows the driving voltage (V_{FD}), the brightness (POD) and the simulated value of the brightness after packaging of Sample 1 (which is the semiconductor structure 100 subjected to the heat treatment process T after the first metal layer 202 and the second metal layer 204 formed thereon) and Sample 2 (which is the semiconductor structure 100 not subjected to the heat treatment process T and without the first metal layer 202 and the second metal layer 204 formed thereon).

TABLE 1

| | Sample 1 | Sample 2 |
|---|---|---|
| driving voltage (V_{FD}) | 3.11 | 3.11 |
| brightness (POD) | 179.96 | 175.65 |
| the simulated value of the | 176.14 | 173.61 |
| brightness after packaging | | |

As shown in Table 1, the driving voltage (V_{FD}) of Sample 1 is similar to that of Sample 2. However, the brightness (POD) of Sample 1 is about 2.5% greater than that of Sample 2. Moreover, the simulated value of the brightness after packaging of Sample 1 is about 1.5% greater than that of Sample 2. Accordingly, the method of manufacturing a semiconductor device provided by the present embodiment can effectively improve the brightness compared to the method of manufacturing a semiconductor device without the first metal layer 202 and the second metal layer 204 formed on the semiconductor structure 100 and without performing the heat treatment process.

Table 2 shows the driving voltage (V_{FD}) and the brightness (POD) of Sample 3 (in which the heat treatment process T is performed before the mesa etching process) and Sample 4 (in which the heat treatment process T is performed after the mesa etching process). As shown in Table 2, the brightness of Sample 3 is slightly greater than that of Sample 4 by about 0.15%. Moreover, the driving voltage (V_{FD}) of Sample 3 is significantly lower than that of Sample 4 by 0.08V. Accordingly, the method of manufacturing a semiconductor device in which the heat treatment process T is performed before the mesa etching process can provide lower driving voltage compared to the method of manufacturing a semiconductor device in which the heat treatment process T is performed after the mesa etching process.

TABLE 2

| | Sample 3 | Sample 4 |
|---|---|---|
| driving voltage (V_{FD}) | 3.07 | 3.15 |
| brightness (POD) | 197.23 | 196.98 |

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method of manufacturing a semiconductor device, comprising:
providing a semiconductor structure, including a sequential stack of an n-type semiconductor layer, an active layer, and a p-type semiconductor layer;
forming a first metal layer and a second metal layer on the semiconductor structure, wherein the second metal layer is disposed on the first metal layer;
performing a heat treatment process such that the first metal layer is oxidized to form a first metal oxide layer and the second metal layer is reversed to form a second metallic compound layer between the first metal oxide layer and the p-type semiconductor layer;
removing the first metal oxide layer and the second metallic compound layer; and
performing a mesa etching process after performing the heat treatment process, to remove a part of the p-type semiconductor layer, a part of the active layer, and a part of the n-type semiconductor layer, to form a mesa region exposing another part of the n-type semiconductor layer.

2. The method as claimed in claim 1, wherein a work function of the first metal layer and a work function of the second metal layer are greater than a work function of the p-type semiconductor layer.

3. The method as claimed in claim 1, further comprising forming a current-spreading layer on the p-type semiconductor layer after removing the first metal oxide layer and the second metallic compound layer.

4. The method as claimed in claim 3, wherein the current-spreading layer comprises a transparent conductive layer, the transparent conductive layer comprises a nickel/gold stack or an oxide layer.

5. The method as claimed in claim 1, wherein the first metal layer includes nickel (Ni), platinum (Pt), or rhodium (Rh).

6. The method as claimed in claim 1, wherein the second metal layer comprises gold.

7. The method as claimed in claim 1, wherein the heat treatment process is performed at a temperature in a range of 100-800° C.

8. The method as claimed in claim 1, wherein the heat treatment process is performed at a temperature in a range of 200-400° C.

9. The method as claimed in claim 1, wherein the heat treatment process is performed in an atmosphere containing nitrogen and oxygen.

10. The method as claimed in claim 1, wherein the first metal oxide layer and the second metallic compound layer are removed using an etching solution having a pH value less than 10.

11. The method as claimed in claim 1, wherein the n-type semiconductor layer, the active layer and the p-type semiconductor layer constitute a light-emitting diode structure.
